(19) United States
(12) Patent Application Publication
(10) Pub. No.: US 2010/0086198 A1
(43) Pub. Date: Apr. 8, 2010

(54) PRINTED CIRCUIT BOARD, LOCATING SYSTEM AND METHOD THEREOF

(75) Inventor: Pei-Chong Tang, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/556,542

(22) Filed: Sep. 9, 2009

(30) Foreign Application Priority Data
Oct. 6, 2008 (CN) 200810304737.7

(51) Int. Cl. G06K 9/00; H05K 1/00

(52) U.S. Cl. 382/151; 174/250

(57) ABSTRACT

A printed circuit board includes a substantially rectangular circuit portion including operation points for connecting with electronic components, and a first margin portion adjacent to the circuit portion. The first margin portion includes groups of reference marks arranged in a first row parallel to a side of the printed circuit board. A related locating system and a locating method for locating position of the operation points of the printed circuit board are also disclosed.

### BACKGROUND

1. Field of the Invention

The present disclosure generally relates to printed circuit boards.

2. Description of Related Art

A printed circuit board (PCB) typically includes a circuit portion having one or more conducting layers (typically made of thin copper foil) laminated onto a non-conductive substrate, and a margin portion surrounding the circuit portion. The circuit portion typically includes numerous operation points connected with conducting traces in the conducting layers. The operation points are configured to connect to electronic components, such as semiconductor chips, resistors, capacitors, etc.

During manufacturing, the PCB may be conveyed by a feeding mechanism to various operation stations where electronic components are mounted on the PCB. The feeding mechanism typically includes a conveyor belt continuously moving to carry the PCB. When mounting the electronic components on the PCB board, a timer and a sensor are used to estimate the current position of the PCB board, such that an automated mounting equipment is able to mount the component on the PCB. However, the PCB may slip on the surface of the conveyor belt and the position of the PCB may not be properly ascertained by the timer and sensor. As a result, the electronic components may be placed at wrong points/positions on the PCB.

Therefore, an improved printed circuit board, and a locating system and a locating method for seeking out and determining a location/coordinates of the printed circuit board are needed in the industry to address the aforementioned deficiency.

### BRIEF DESCRIPTION OF THE DRAWINGS

FIG. 1 is a schematic diagram showing a printed circuit board in accordance with a first exemplary embodiment, the printed circuit board includes two margin portions, and one of the two margin portions includes six groups of reference marks.

FIG. 2 is a schematic diagram showing a printed circuit board in accordance with a second exemplary embodiment, the printed circuit board includes two margin portions, and each margin portion includes six groups of reference marks.

FIG. 3 is a schematic diagram showing four parts of the margin portions of four printed circuit boards in accordance with other four embodiments, each margin portion includes five groups of reference marks.

FIG. 4 is a schematic diagram showing a locating system for locating operation points of the printed circuit board of FIG. 2 in accordance with an exemplary embodiment, the locating system includes two mark detecting mechanisms and a feeding mechanism.

FIG. 5 is a block diagram showing the locating system of FIG. 4.

FIG. 6 is a schematic diagram showing a part of the margin portion of FIG. 2 and four capture ranges of one of the mark detecting mechanism of FIG. 4.

FIG. 7 is a schematic diagram showing five images captured by one of the mark detecting mechanism of FIG. 4.

FIG. 8 is a schematic diagram showing a printed circuit board positioned on the feeding mechanism of FIG. 4.

FIG. 9 is a schematic block diagram showing a mathematic model for illustrating a working principle of the locating device of FIG. 4.

FIG. 10 is a flowchart showing a locating method for locating operation points of a printed circuit board in accordance with a first exemplary embodiment.

FIG. 11 is a flowchart showing a locating method for locating operation points of a printed circuit board in accordance with a second exemplary embodiment

### DETAILED DESCRIPTION OF CERTAIN INVENTIVE EMBODIMENTS

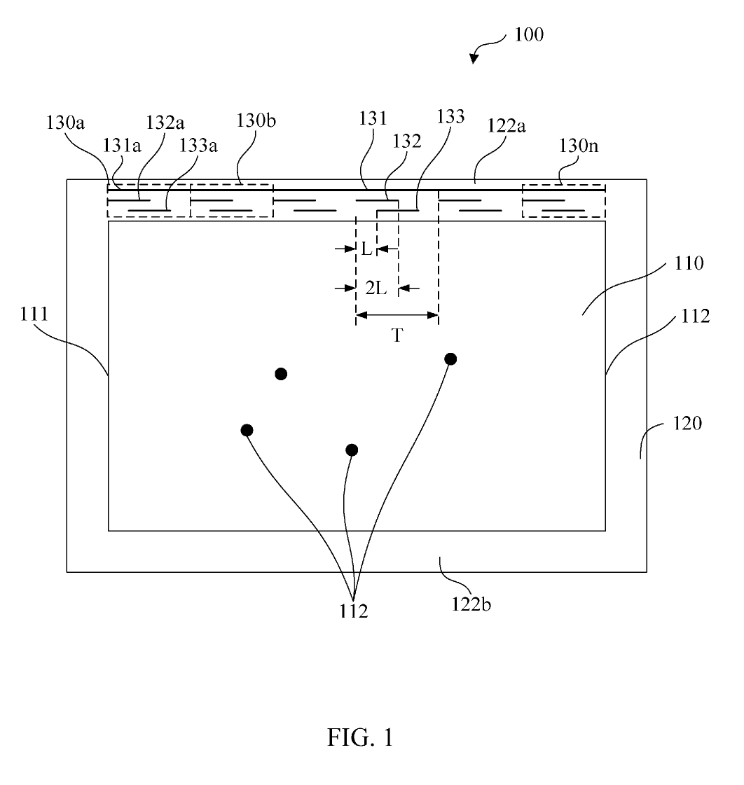

Referring to FIG. 1, a substantially rectangular printed circuit board (PCB) 100 in accordance with a first exemplary embodiment is illustrated. The PCB 100 includes a substantially rectangular circuit portion 110 and a margin portion 120 surrounding the circuit portion 110. The circuit portion 110 includes a plurality of operation points 112 for connecting with electronic components (not shown), such as semiconductor chips, resistors, capacitors, etc. The margin portion 120 may be used for protecting the circuit portion 110 from damages, by being bumped for example, and may be used as an area to set location holes. The margin portion 120 includes a first rectangular margin portion (first margin portion in short) 122a and a second rectangular margin portion (hereinafter, second margin portion) 122b disposed at two opposite long sides of the circuit portion 110.

In the embodiment, the first margin portion 122a includes a line 131 parallel to long sides of the PCB 100, a first dashed line 132, and a second dashed line 133 parallel to the line 131. Dash portions of the first and second dashed lines 132, 133 are staggered with respect to each other. The line 131 starts from an extended line (not shown) of a short side 111 of the circuit portion 110, and ends at an extended line (not shown) of the other short side 112 of the circuit portion 110. The first dashed line 132 starts from the extended line of the short side 111. The second dashed line 133 starts half a length of the dash portions from the extended line of the short side 111. In other embodiments, the line 131, the first dashed line 132 and the second dashed line 133 may be parallel to short sides of the PCB 100.

The line 131, the first dashed line 132, and the second dashed line 133 are considered as consisting of a plurality of groups 130a, 130b . . . 130n (enclosed by the broken line rectangle, hereinafter 130a-130n in short, “n” is an integer, n=6 in FIG. 1). Each of the groups 130a-130n includes a segment 131a which is a part of the line 131, a dash portion 132a and a blank portion (not labeled) of the first dashed line 132, and a dash portion 133a and two blank portion at opposite sides of the dash portion 133a of the second dashed line 133. The segment 131a, the dash portion 132a, and the dash portion 133a are considered as key marks (in other words, reference marks) for being used to determine current positions of the operation points 112 when or after the PCB 100 is moved. In practice, the terminals (ends) of the dash portions 132a, 133a are considered as key points used for determining the current positions of the operation points 112, and two terminals of the line 131 are also considered as key points respectively being used to indicate the short sides 111, 112 of the circuit portion 110. The real positions of the key points and the real positions of the operation points 112 may be associated and pre-stored.

Preferably, a length of each segment 131a is T that equals to 4 L, and a length of each dash portion 132a/133a is 2 L. A distance between the line 131 and the first dashed line 132, preferably, equals to a distance between the first dashed line 132 and the second dashed line 133.

When the PCB 100 is measured or checked by an automated test equipment (ATE), or mounted thereon some electronic components by an automated mounting equipment, a current position of each target operation point 110 may be determined by detecting and determining current positions of two nearby key points (namely, two key points near the target operation point 110) based on the pre-stored real positions of the target operation point 110 and the two nearby key points. Therefore, a location precision of the operation points 112 is improved.

To sum up, the first margin portion 122a includes a plurality of groups 130a-130n of reference marks arranged in a first row parallel to a side of the PCB 100. The reference marks are configured for being used to determine current positions of the operation points 112 when or after the PCB 100 is moved. The groups 130a-130n of reference marks are evenly disposed in the first margin portion 122a. Each of the groups 130a-130n includes at least two key marks different from each other, and each key mark may include at least a key point. In other embodiments, each group 130a may include at least two similar key marks.

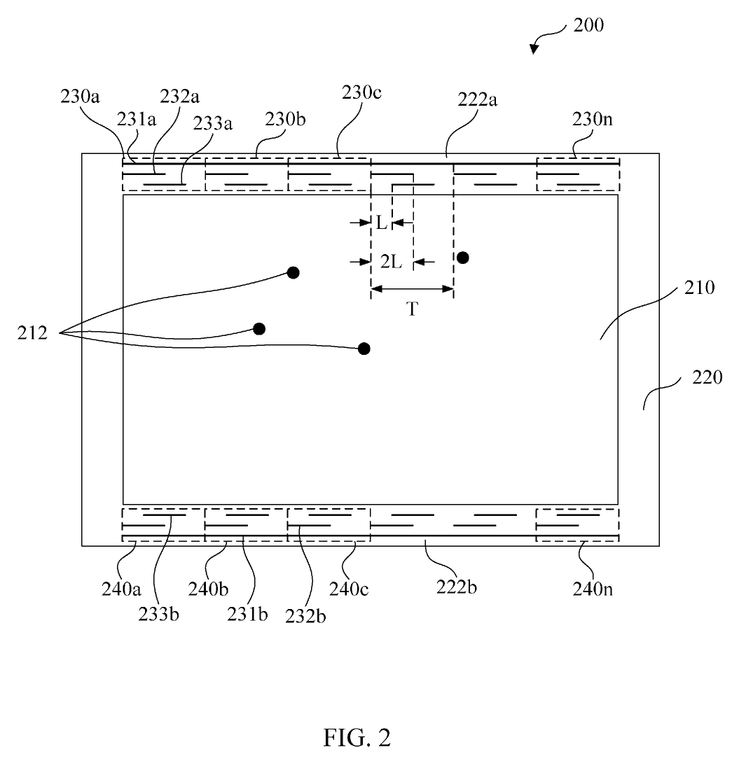

Referring to FIG. 2, a substantially rectangular printed circuit board (PCB) 200 in accordance with a second exemplary embodiment is illustrated. The PCB 200 has similar configurations with the PCB 100. When compared with the PCB 100, a second margin portion 222b of the PCB 200 may further includes a plurality of groups 240a, 240b . . . 240n (enclosed by the broken line rectangle, hereinafter 240a-240n in short) of reference marks arranged in a second row parallel to a side of the PCB 200.

The groups 240a-240n of reference marks arranged in the second margin portion 222b are similar to and in proportion to groups 230a-230n of reference marks arranged in the first margin portion 222a. In the embodiment, each of the groups 230a-230n (240a-240n) includes three key marks 231a, 232a, 233a (231b, 232b, 233b) similar to the key marks 131a, 132a, 133a in FIG. 1 (that is, the segment 131a, the dash portion 132a, and the dash portion 133a). In other embodiments, two opposite groups, 230a and 240a for example, may be staggered in a direction perpendicular to a connecting line of the circuit portion 210 and the first margin portion 222a.

Terminals of dash portions of the key marks 232a, 232b, 233a, 233b, may be considered as key points used for determining current positions of operation points 212. All the key marks 231a (231b) are connected together to form a continuous line, two terminals of which may also be considered as key points respectively being used to indicate two opposite short sides of the circuit portion 210. Real positions of the key points and real positions of the operation points 212 may be associated and pre-stored.

When the PCB 200 is measured or checked by an automated test equipment (ATE), or mounted thereon some electronic components by an automated mounting equipment, a current position of each target operation point 210 may be determined by detecting and determining current positions of two nearby key points respectively disposed in the first and second margin portions 222a, 222b based on the pre-stored real positions of the target operation point 110 and the two nearby key points. Generally, a width between the two nearby key points respectively disposed in the first and second margin portions 222a, 222b is larger than that between two nearby key points disposed in one of the first and second margin portions 222a, 222b. Thus an identify-ability of the two nearby key points respectively disposed in the first and second margin portions 222a, 222b is higher. Therefore, a location precision of the operation points 212 is improved.

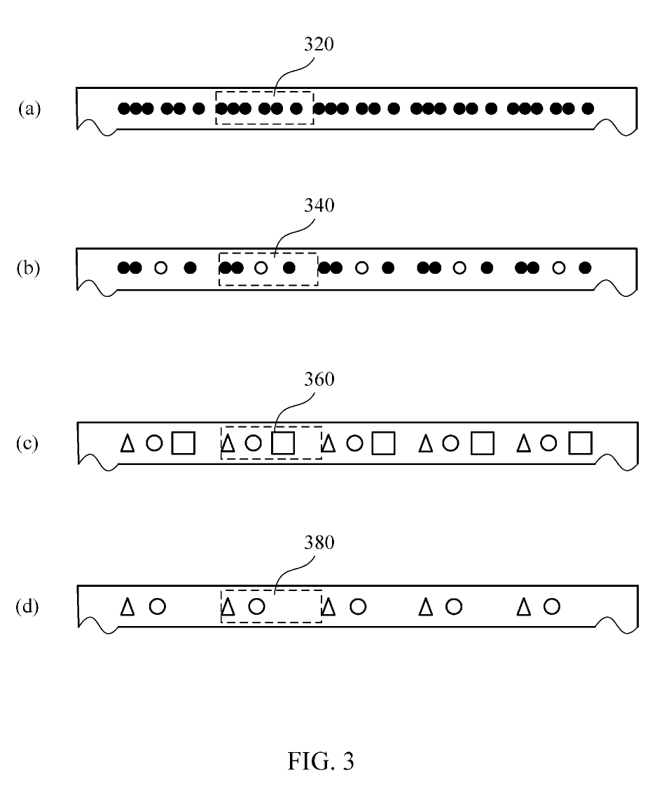

In other embodiments, each group of reference marks may include key marks different from that in FIGS. 1 and 2. Each group of reference marks, preferably, includes at least two key marks different from each other, such that which group of reference marks is detected can be easily identified. For example, referring to FIG. 3a, a group 320 of reference marks may include a first key mark including three conterminous dots (or holes), a second key mark including two conterminous dots (or holes), and a third key mark including a single dots (or hole). The dots may be solder pads, or made of copper. In another embodiment, referring to FIG. 3b, a group 340 of reference marks may include a first key mark including two black conterminous dots (or holes), a second key mark including a single dot having a tinged color (a solder pad for example), and a third key mark including a single black dots (made of copper or being a hole). In a further embodiment, referring to FIG. 3c, a group 360 of reference marks may include a first key mark having a shape of triangle, a second key mark having a shape of circle, and a third key having a shape of square. In another embodiment, referring to FIG. 3d, a group 380 of reference marks may include a first key mark and a second key mark similar to the first and second key marks in FIG. 3c.

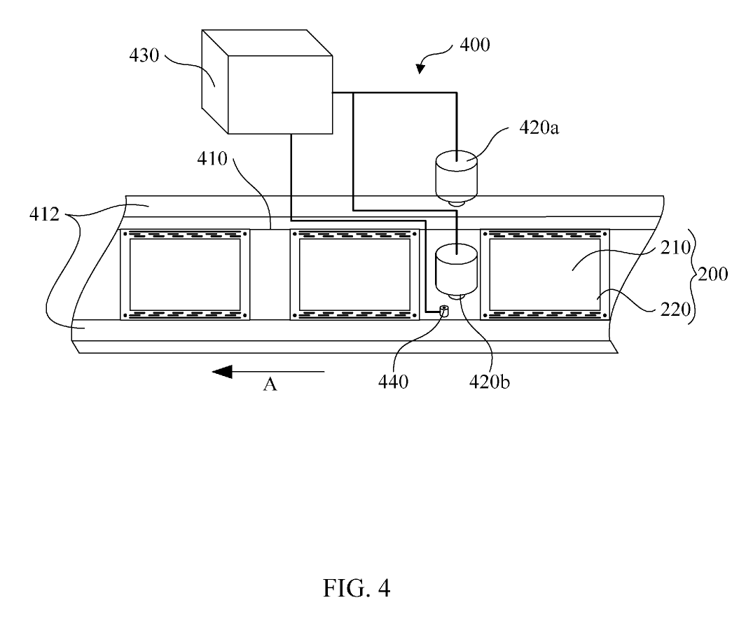

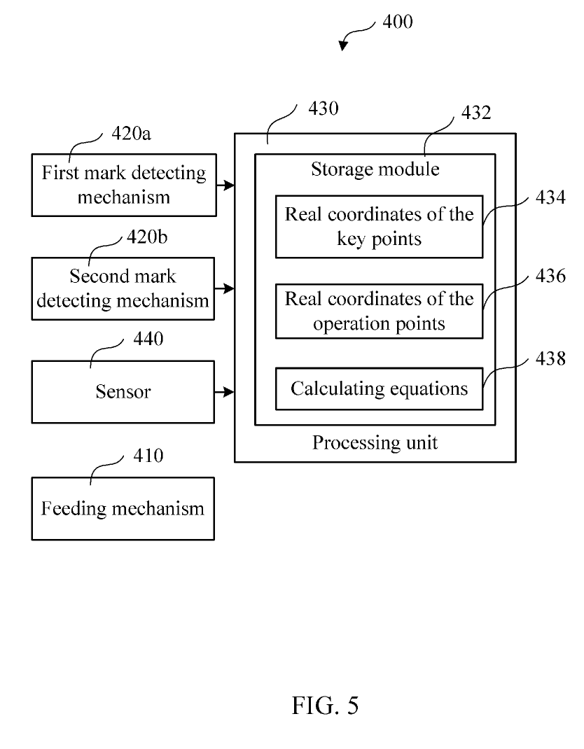

Referring to FIGS. 4-5, a locating system 400 for locating operation points of a printed circuit board (PCB) in accordance with an exemplary embodiment may include a feeding mechanism 410, a first mark detecting mechanism 420a, a second mark detecting mechanism 420b, a processing unit 430, and a sensor 440. The PCB may be the PCB 100 of FIG. 1, or the PCB 200 of FIG. 2, or one of the PCB of FIG. 3. In the embodiment, the PCB is the PCB 200 of FIG. 2. The locating system 400 is capable of locating any operation point 212 on the PCB 200 based on the groups 230a-230n, 240a-240n of reference marks on the PCB 200 even when the PCB 200 slips and/or rotates on the feeding mechanism 410 which is continuously moving.

The feeding mechanism 410 is configured for conveying the PCB 200 to predetermined positions, such as various operation stations, to measure, test, or mount electronic components on the PCB 200. The feeding mechanism 410 preferably includes side walls 412 to prevent the PCB 200 from falling off the feeding mechanism 410. A moving direction of the feeding mechanism 410 is labeled as “A”. When the PCB 200 is positioned on the feeding mechanism 410, the groups 230a-230n are arranged in a first row parallel to the moving direction A of the feeding mechanism 410, and the groups 240a-240n are arranged in the second row also parallel to the moving direction A.

The first mark detecting mechanism 420a and the second mark detecting mechanism 420b are configured for detecting position information of the plurality of groups 230a-230n, 240a-240n of reference marks of the PCB 200. In the embodiment, the first and second mark detecting mechanisms 420a, 420b are imaging apparatuses, such as cameras. The first mark detecting mechanism 420a is unmovable disposed above a side wall 412 of the feeding mechanism 410 to capture a series of images of the first margin portion 222a at predetermined time intervals to get position information of the plurality of groups 230a-230n of reference marks. The second mark detecting mechanism 420b is unmovable disposed above the other side wall 412 of the feeding mechanism 410 to capture a series of images of the second margin portion 222b at predetermined time intervals to get position information of the plurality of groups 240a-240n of reference marks. Preferably, the first and second mark detecting mechanisms 420a, 420b operate synchronously. Because two mark detecting mechanisms are utilized, each of the first and second mark detecting mechanisms 420a, 420b can only detect a small area of the PCB 200, thus a detecting precision of the locating system 400 is improved.

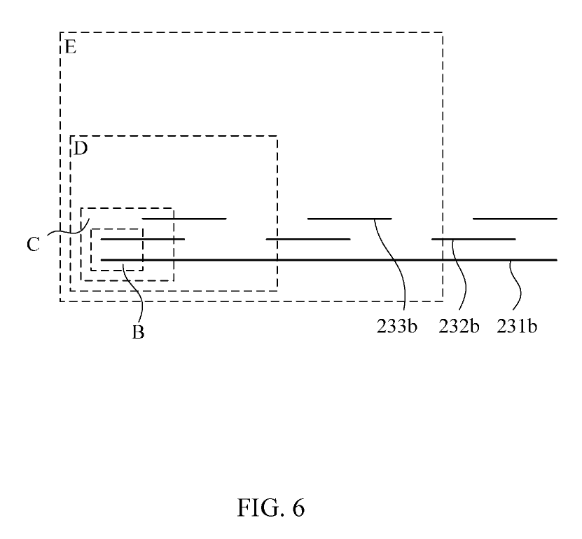

A capture range (namely, a detecting range) of each of the first and second mark detecting mechanisms 420a, 420b, preferably, cover at least a key point, such that each image includes at least a key point. Referring to FIG. 6, four capture ranges B, C, D, E are illustrated, the capture range B is too small to cover the key mark 233b, and the capture range E is too large. The capture range D covers all the key marks in one of the groups 240a-240n, and the capture range C covers at most two key marks. In the embodiment, because two mark detecting mechanisms are utilized, the first and second mark detecting mechanisms 420a, 420b have the capture range C. Preferably, a width of the capture range is longer than L, and shorter than 2 L.

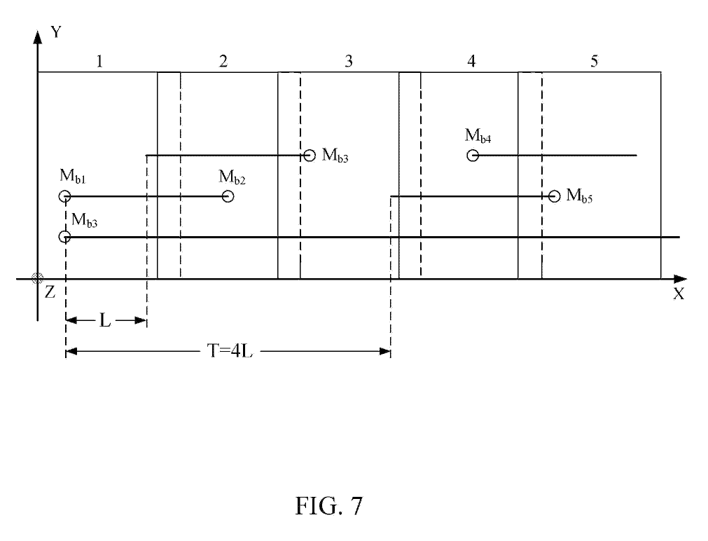

The capture time interval of the first and second mark detecting mechanisms 420a, 420b preferably cooperate with a moving speed of the feeding mechanism 410 to make two neighboring images of the series of images partly overlaps. Such that none of the key marks is lost by the first and second mark detecting mechanisms 420a, 420b, and the detected key mark is easily to be determined. Referring to FIG. 7, five images (labeled as 1-5 above respective images) in series captured by the second mark detecting mechanism 420b is illustrated. Evidently, three series images can cover a group of reference marks, and each image includes at most two key points.

Referring back to FIGS. 4 and 5, the sensor 440 is configured for generating a start signal when determining that the PCB 200 enters the capture range of the first and second mark detecting mechanisms 420a, 420b, and generating an end signal when determining that the PCB 200 leaves the capture range. The first and second mark detecting mechanisms 420a, 420b start to capture the images in responding to the start signal, and stop in responding to the end signal. Under this condition, both opposite key points (one of which is labeled as Mb3 in FIG. 7) of the continuous lines formed by the key marks 231a, 231b can be generally captured even when the PCB 200 slips and/or rotates on the feeding mechanism 410. In other embodiments, the sensor 440 may be omitted, as the continuous lines formed by the key marks 231a, 231b may be used to indicate a start and an end of the circuit portion 210.

The processing unit 430 may be a computer. In the embodiment, the processing unit 430 includes a storage module 432 (see FIG. 5). The storage module 432 may include a first storage unit 434 for storing real coordinates of the key points, a second storage unit 436 for storing real coordinates of the operation points 212 on the PCB 200, and a third storage unit 438 for storing calculating equations. The processing unit 430 is configured for determining position information of the operation points 212 based on the position information of the plurality of groups 230a-230n, 240a-240n of reference marks received from the first and second mark detecting mechanisms 420a, 420b, real coordinates of the key points and the operation points 212 stored in the storage module 432, and the calculating equations. The processing unit 430 is further used for enabling the first and second mark detecting mechanisms 420a, 420b when receiving the start signal from the sensor 440, and disabling the first and second mark detecting mechanisms 420a, 420b when receiving the end signal from the sensor 440.

In practice, at every predetermined time interval, the processing unit 430 receives a pair of images, synchronously captured by the first and second mark detecting mechanisms 420a, 420b, of the first and second margin portions 222a, 222b. The processing unit 430 then identifies an order number of the pair of images, such as the number labeled above the images in FIG. 7. The processing unit 430 may include a timer (not shown) keeping track of an operation time of the first and second mark detecting mechanisms 420a, 420b when the PCB 200 is in the capture range in responding to the start signal, and determine the order number of the pair of images according to the operation time. Then the processing unit 430 determines a key point in each image of the pair of images, and determines current coordinates of the two key points in the pair of images. For example, referring to FIG. 7, a key point Mb1 is selected in the image “1”, a key point Mb2 is selected in the image “2”, a key point Mb3 is selected in the image “3”, etc. After that, the processing unit 430 may retrieve real coordinates of the two key points from the storage module 432 according to the order number of the pair of images, and retrieve real coordinates of one or more operation points 212 near the pair of key points. Finally, the processing unit 430 determines current coordinates of the one or more operation points 212 near the pair of key points according to the corresponding real coordinates and current coordinates. After the current coordinates of the one or more operation points 212 have been determined, the one or more operation points 212 may be immediately measured, checked by an automated test equipment (ATE) or mounted thereon predetermined electronic components by an automated mounting equipment.

Because current position of each operation points 212 in the PCB 200 can be determined based on two nearby opposite groups of reference marks, 230a and 240a for example, whose current positions are determined based on a pair of synchronously captured images, a location precision of the operation points 212 can be insured even when the PCB 200 slips and becomes reoriented with respect to side walls of the feeding mechanism 410.

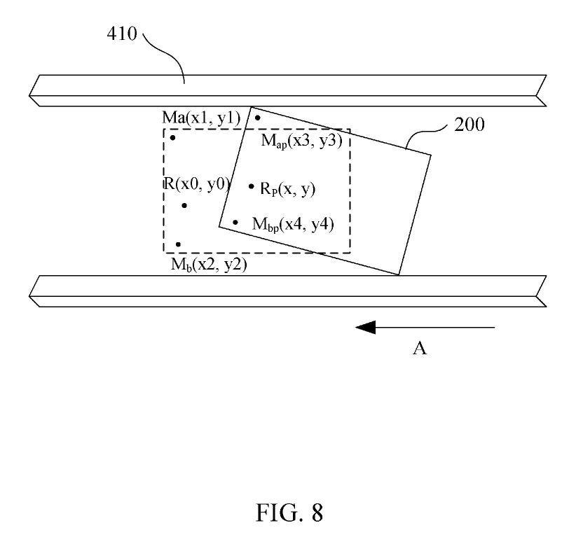

Referring to FIG. 8, a schematic diagram illustrates the PCB 200 reoriented with respect to side walls (or moving direction A) of the feeding mechanism 410. A desired original position of the PCB is defined by a broken line. The key point Map on the PCB 200 in a current position is the key point Ma in the desired original position, the key point Mbp in the current position is the key point Mb in the desired original position, and the operation point Rp in the current position is the operation point R in the desired original position. Supposing real coordinates of the key point Ma is (x1, y1), real coordinates of the key point Mb is (x2, y2), and real coordinates of the operation point R is (x0, y0). Further supposing current coordinates of the key point Map is (x3, y3), current coordinates of the key point Mbp is (x4, y4), and current coordinates of the operation point Rp is (x, y).

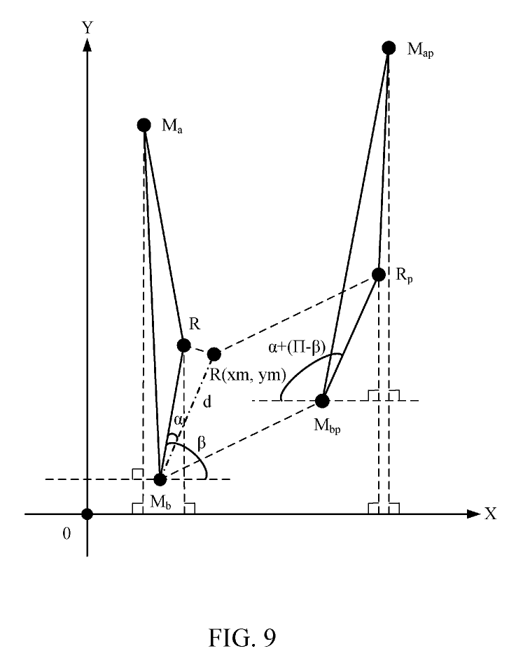

Referring also to FIG. 9, a mathematic model is illustrated to show how the processing unit 430 calculates the current coordinates of the operation point Rp. Supposing an angle between a line defined by the key points Ma, Mb and a line defined by the key points Map, Mbp is a, and an angle between a line defined by the operation point R and the key point Mb and the horizontal axis (X axis) is β. It is understandable, after the operation point R(x0, y0) rotates the angle of a around the key point Mb(x2, y2), the operation point Rm(xm, ym) is determined. Therefore, the angle a can be calculated applying a first calculating equation (1):

α=arctan((y1−y2)/(x1−x2))−arctan((y3−y4)/(x3−x4)) (1)

The angle β can be calculated applying a second calculating equation (2):

β=arctan((y0−y2)/(x0−x2)) (2)

A length “d” between the operation point Rm and the key mark Mb can be calculated applying a third calculating equation (3):

d=sqrt((x0−x2)*(x0−x2)+(y0−y2)*(y0−y2)) (3)

The coordinates (xm, ym) can be calculated applying a fourth calculating equation (4):

xm=x2−d*cos(α+Π−β), ym=y2+d*sin(α+Π−β) (4)

The coordinates (x, y) can be calculated applying a fifth calculating equation (5):

x=x4−d*cos(α+Π−β), y=y4+d*sin(α+Π−β) (5)

A horizontal moving distance “dy” of the operation point R can be calculated applying a sixth calculating equation (6):

dy=y−y0=y4+d sin(α+Π−β)−y0 (6)

A vertical moving distance “dy” of the operation point R can be calculated applying a seventh calculating equation (7):

dx=x−x0=x4−d cos(α+Π−β)−x0 (7)

The calculating equations (1)-(3) and (5)-(7) may be stored in the third storage unit 438 of the storage module 432.

In other embodiment, when the locating system 400 is used to locating operation points of a PCB similar to the PCB of FIG. 1, one of the first and second mark detecting mechanisms 420a, 420b may be disabled. Under this condition, the capture range of the first and second mark detecting mechanisms 420a, 420b may cover at least two key points, such that each operation point on the PCB can be determined using one image captured by the one of the first and second mark detecting mechanisms 420a, 420b.

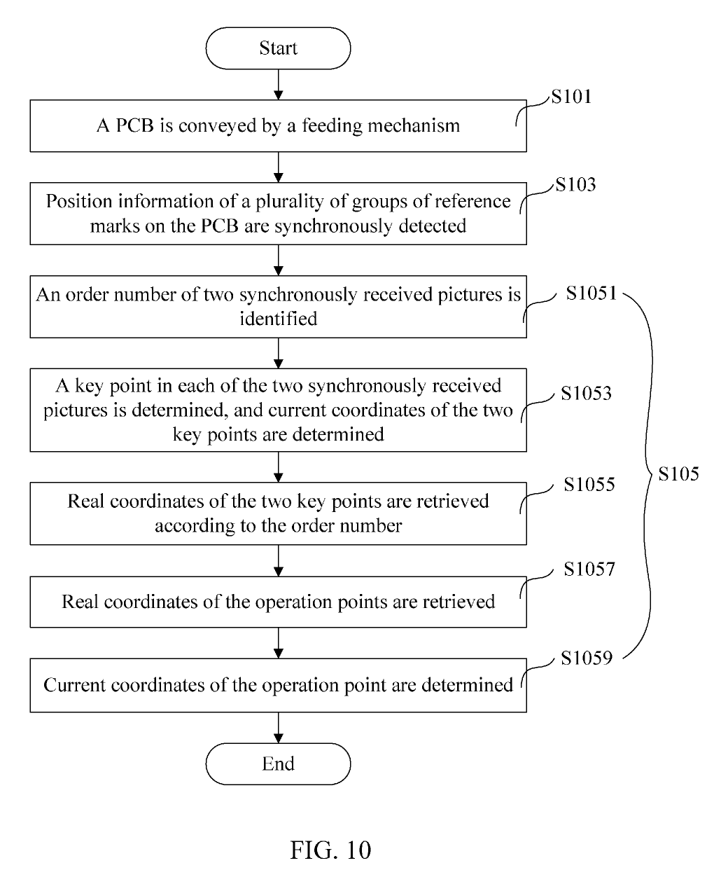

Referring to FIG. 10, a locating method for locating operation points of a printed circuit board (PCB) in accordance with a first exemplary embodiment is illustrated. The PCB may be the PCB 100 of FIG. 1, or the PCB 200 of FIG. 2, or one of the PCB of FIG. 3. In the embodiment, the PCB is the PCB 200 of FIG. 2. The locating method is capable of locating any operation point 212 on the PCB 200 based on the groups 230a-230n, 240a-240n of reference marks on the PCB 200 even when the PCB 200 slips and/or rotates on a feeding mechanism which is continuously moving. Detailed steps of the locating method used by a position device (the locating device 400 for example) are set forth as follows.

In step S101, the PCB is conveyed by the feeding mechanism.

In step S103, position information of the plurality of groups 230a-230n, 240a-240n of reference marks are synchronously detected by two mark detecting mechanisms. In the embodiment, when a start signal has been received, a series of images of each of the first and second margin portions 222a, 222b is captured at predetermined time intervals to get position information of the plurality of groups 230a-230n, 240a-240n of reference marks by respective mark detecting mechanisms. Each image includes at least a key point. When an end signal has been received, the capture action is disabled. The start signal signals that the PCB 200 has entered a capture range of one of the two mark detecting mechanisms, and the end signal signals that the PCB 200 has left capture ranges of the two mark detecting mechanisms. Preferably, the two mark detecting mechanisms are unmovable fixed above a moving trace of the PCB 200.

In step S105, position information of the operation points 212 are determined according to the position information of the plurality of groups 230a-230n, 240a-240n of reference marks. Detailed sub-steps of step S105 are set forth as follows.

In step S1051, an order number of two synchronously received images received from the two mark detecting mechanisms is identified. In the embodiment, a timer may be used to keep track of an operation time of the two mark detecting mechanisms when the PCB is in the capture range of the two mark detecting mechanisms. The order number may be determined based on the operation time.

In step S1053, a key point in each of the two synchronously received images is determined, and current coordinates of the two key points are determined. Assuming current coordinates of the two key points are (x3, y3) and (x4, y4).

In step S1055, real coordinates of the two key points are retrieved according to the order number, the real coordinates of the two key points are pre-stored. Assuming real coordinates of the two key points are (x1, y1) and (x2, y2).

In step S1057, pre-stored real coordinates of the operation points 212 are retrieved. In the embodiment, only real coordinates of one or more operation points 212 near the two key points are retrieved. Assuming only one operation point is determined to be located, and real coordinates of the operation point is (x0, y0).

In step S1059, current coordinates (x, y) of the operation point are determined according to the real coordinates of the two key points and the operation point, and the current coordinates of the two key points. In the embodiment, the coordinates (x, y) can be calculated applying the following pre-stored calculating equations:

x=x4−d*cos(α+Π−β), y=y4+d*sin(α+Π−β), α=arctan((y1−y2)/(x1−x2))−arctan((y3−y4)/(x3−x4)), β=arctan((y0−y2)/(x0−x2)), and d=sqrt((x0−x2)*(x0−x2)+(y0−y2)*(y0−y2)).

Preferably, a horizontal moving distance “dx”, and a vertical moving distance “dy” of the operation point can be calculated applying the following pre-stored calculating equations:

dx=x−x0=x4−d cos(α+Π−β)−x0, dy=y−y0=y4+d sin(α+Π−β)−y0.

Because current position of each operation points 212 in the PCB 200 can be determined based on two nearby opposite groups 222a, 222b of reference marks, whose current positions are determined based on a pair of synchronously captured images, a location precision of the operation points 212 can be insured even when the PCB 200 slips and becomes reoriented with respect to side walls of a feeding mechanism.

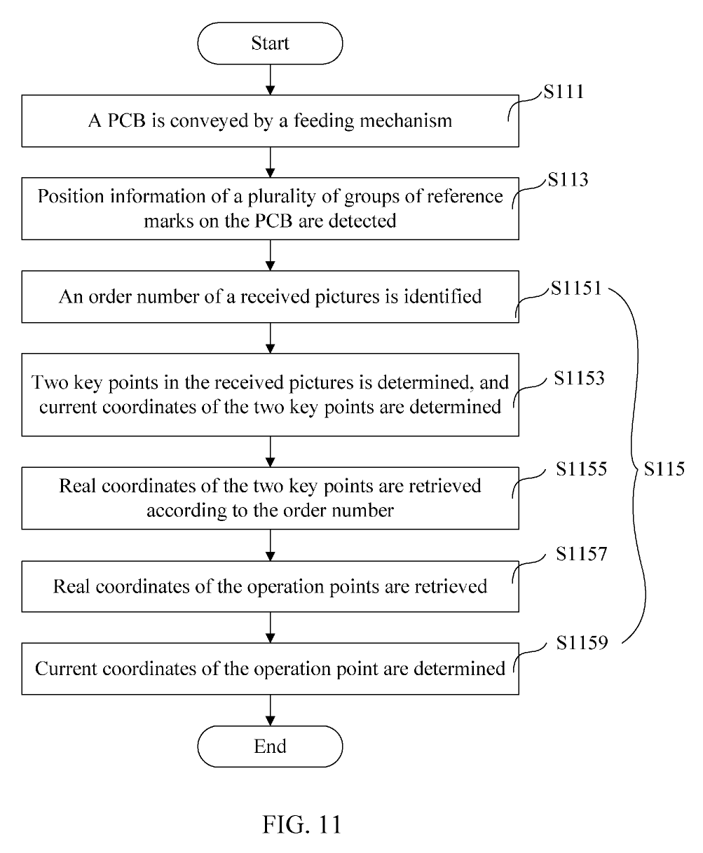

Referring to FIG. 11, a locating method for locating operation points of a printed circuit board (PCB) in accordance with a second exemplary embodiment is illustrated. In the embodiment, the PCB may be the PCB 100 of FIG. 1, or similar to the PCB 100. The locating method is capable of locating any operation point 112 on the PCB 100 based on the groups 130a-130n of reference marks on the PCB 100 even when the PCB 100 slips and/or rotates on a feeding mechanism which is continuously moving. Detailed steps of the locating method used by a position device (the locating device 400 for example) are set forth as follows.

In step S111, the PCB is conveyed by the feeding mechanism.

In step S113, position information of the plurality of groups 130a-130n of reference marks are detected by a mark detecting mechanism. In the embodiment, when a start signal has been received, a series of images of the first margin portion 122a is captured at predetermined time intervals to get position information of the plurality of groups 130a-130n of reference marks by the mark detecting mechanism. Each image includes at least two key points. When an end signal has been received, the capture action is disabled. The start signal signals that the PCB 200 has enter a capture range of the mark detecting mechanism, and the end signal signals that the PCB 200 has left the capture range of the mark detecting mechanism. Preferably, the mark detecting mechanism is unmovable fixed above a moving trace of the PCB 200.

In step S115, position information of the operation points 112 are determined according to the position information of the plurality of groups 130a-130n of reference marks. Detailed sub-steps of step S115 are set forth as follows.

In step S1151, an order number of a received image received from the mark detecting mechanism is identified. In the embodiment, a timer may be used to keep track of an operation time of the mark detecting mechanism when the PCB is in the capture range of the mark detecting mechanism. The order number may be determined based on the operation time.

In step S1153, two key point in the received image are determined, and current coordinates of the two key points are determined. Assuming current coordinates of the two key points are (x3, y3) and (x4, y4).

In step S1155, real coordinates of the two key points are retrieved according to the order number, the real coordinates of the two key points are pre-stored. Assuming real coordinates of the two key points are (x1, y1) and (x2, y2).

In step S1157, pre-stored real coordinates of the operation points 212 are retrieved. In the embodiment, only real coordinates of one or more operation points 212 near the two key points are retrieved. Assuming only one operation point is determined to be located, and real coordinates of the operation point is (x0, y0).

In step S1159, current coordinates (x, y) of the operation point are determined according to the real coordinates of the two key points and the operation point, and the current coordinates of the two key points. In the embodiment, the coordinates (x, y) can be calculated applying the similar pre-stored calculating equations to those used in the first embodiment:

x=x4−d*cos(α+Π−β), y=y4+d*sin(α+Π−β), α=arctan((y1−y2)/(x1−x2))−arctan((y3−y4)/(x3−x4)), β=arctan((y0−y2)/(x0−x2)), and d=sqrt((x0−x2)*(x0−x2)+(y0−y2)*(y0−y2)).

Preferably, a horizontal moving distance “dx”, and a vertical moving distance “dy” of the operation point can be calculated applying the following pre-stored calculating equations:

dx=x−x0=x4−d cos(α+Π−β)−x0, dy=y−y0=y4+d sin(α+Π−β)−y0.

Because current position of each operation points 112 in the PCB 100 can be determined based on two nearby key points in one or two groups 130a-130n of reference marks, whose current positions are determined based on a captured image, a location precision of the operation points 112 can be insured even when the PCB 100 slips and becomes reoriented with respect to side walls of the feeding mechanism.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A printed circuit board, comprising:
a substantially rectangular circuit portion comprising a plurality of operation points for connecting with electronic components; and
a first margin portion adjacent to the circuit portion, the first margin portion comprising a plurality of groups of reference marks arranged in a first row parallel to a side of the printed circuit board, the plurality of groups of reference marks capable of being identified for facilitating to determine positions of the plurality of operation points.

2. The printed circuit board of claim 1, wherein each group of reference marks comprises at least two key marks different from each other, and each key mark comprises at least a key point.

3. The printed circuit board of claim 1, wherein the plurality of groups of reference marks are evenly disposed in the first margin portion.

4. The printed circuit board of claim 1, further comprising a second margin portion adjacent to the circuit portion and facing the first margin portion, the second margin portion comprising a plurality of groups of reference marks arranged in a second row parallel to the first row.

5. The printed circuit board of claim 4, wherein each group of reference marks comprises a segment which is a part of a line, a first dash portion of a first dashed line, and a second dash portion of a second dashed line; the line, and the first and second dashed lines are parallel to each other; dash portions of the first dashed line and the second dashed line are staggered with respect to each other.

6. The printed circuit board of claim 5, wherein two terminals of the line are capable of being recognized to indicate a start and an end of the circuit portion respectively.

7. The printed circuit board of claim 5, wherein a length of the segment is two times of a length of each of the first and second dash portions, and the first dash portion and the second dash portion are staggered for a half length of the first dash portion.

8. A locating system for locating operation points of a printed circuit board, the locating system comprising:
a feeding mechanism for conveying thereon the printed circuit board having a first margin portion comprising a plurality of groups of reference marks arranged in a first row, each group of reference marks comprising at least two key points;
a first mark detecting mechanism for detecting position information of the plurality of groups of reference marks; and
a processing unit for determining position information of the operation points according to the position information of the plurality of groups of reference marks.

9. The locating system of claim 8, wherein the operation points are located on a substantially rectangular circuit portion of the printed circuit board, and is configured for connecting with electronic components; the first margin portion is adjacent to the circuit portion; the first row is parallel to a side of the printed circuit board, and the side of the printed circuit board is substantially parallel to a moving direction of the feeding mechanism when the printed circuit board is conveyed by the feeding mechanism.

10. The locating system of claim 9, wherein the first mark detecting mechanism is unmovable disposed above the feeding mechanism.

11. The locating system of claim 10, further comprising a second mark detecting mechanism for detecting position information of a plurality of groups of reference marks arranged in a second row on a second margin portion; the second mark detecting mechanism being unmovable disposed above the feeding mechanism and being operated synchronously with the first mark detecting mechanism; the second margin portion being adjacent to the circuit portion and facing the first margin portion, and the second row being parallel to the first row.

12. The locating system of claim 11, wherein the processing unit determines a first position of a key point of one of the plurality of groups of reference marks arranged in the first row according to the position information received from the first mark detecting mechanism, determines a second position of a key point of one of the plurality of groups of reference marks arranged in the second row according to the position information received from the second mark detecting mechanism, and determines the position information of the operation points according to the first and second positions.

13. The locating system of claim 8, wherein the first mark detecting mechanism is an imaging apparatus.

14. The locating system of claim 8, further comprising a sensor for generating a start signal when determining that the printed circuit board enters a detecting range of the first mark detecting mechanism, the first mark detecting mechanism starts to operate in responding to the start signal.

15. A locating method for locating operation points of a printed circuit board, the locating method comprising:
conveying the printed circuit board having a first margin portion comprising a plurality of groups of reference marks arranged in a first row, each group of reference marks comprising at least two key points;
detecting position information of the plurality of groups of reference marks using a first mark detecting mechanism; and
determining position information of the operation points according to the position information of the plurality of groups of reference marks.

16. The locating method of claim 15, further comprising: detecting position information of a plurality of groups of reference marks arranged in a second row on a second margin portion of the printed circuit board using a second mark detecting mechanism; the second margin portion being adjacent to the circuit portion and facing the first margin portion, the second row being parallel to the first row, the first row being parallel to a side of the printed circuit board, and the side of the printed circuit board being substantially parallel to a moving direction of the printed circuit board when the printed circuit board is conveyed.

17. The locating method of claim 16, wherein the action of detecting position information performed by the first and the second mark detecting mechanisms comprises:
synchronously capture a series of images of each of the first and second margin portions to obtain position information of the plurality of groups of reference marks in the first and second rows, each image comprises at least a key point.

18. The locating method of claim 17, wherein the action of determining position information of the operation points comprises:
identifying an order number of two synchronously received images when receiving the two images from the first and second mark detecting mechanisms;
determining a key point in each of the two images;
determining current coordinates of the two key points in the images;
retrieving real coordinates of the two key points according to the order number, the real coordinates of the two key points are pre-stored;
retrieving pre-stored real coordinates of the operation points; and
determining current coordinates of the operation points according to the real coordinates of the two key points and the operation points, and the current coordinates of the two key points.

19. The locating method of claim 15, wherein the action of detecting position information of the plurality of groups of reference marks comprises:
capturing a series of images of the first margin portion to obtain position information of the plurality of groups of reference marks in the first row, each image comprises at least two key points.

20. The locating method of claim 19, wherein the action of determining position information of the operation points comprises:
identifying an order number of a received image when receiving the image from the first mark detecting mechanism;
determining two key points in the received image;
determining current coordinates of the two key points;
retrieving real coordinates of the two key points according to the order number, the real coordinates of the two key points are pre-stored;
retrieving pre-stored real coordinates of the operation points; and
determining current coordinates of the operation points according to the real coordinates of the two key points and the operation points, and the current coordinates of the two key points.
